(19) United States
(12) Patent Application Publication
(10) Pub. No.: US 2025/0257469 A1
(43) Pub. Date: Aug. 14, 2025

(54) METAL COMPONENT INCLUDING AN INTERMETALLIC COMPOUND LAYER AND METHOD FOR MANUFACTURING THEREOF

(71) Applicant: Infineon Technologies AG, Neubiberg (DE)

(72) Inventors: Pei Luan POK, Melaka (MY); Swee Kah LEE, Melaka (MY)

(73) Assignee: Infineon Technologies AG, Neubiberg (DE)

(21) Appl. No.: 19/038,265

(22) Filed: Jan. 27, 2025

(30) Foreign Application Priority Data
Feb. 28, 2024 (DE) 10 2024 105 602.9

(51) Int. Cl. C23C 28/00; C23C 2/08; C23C 2/28

(52) U.S. Cl. CPC C23C 28/321; C23C 2/08; C23C 2/285; C23C 28/325; C23C 28/345

(57) ABSTRACT

A metal component and an electronic device including a metal component is disclosed. In one example, the metal component includes a metallic core material, a first metal layer arranged over the metallic core material, a second metal layer arranged over the first metal layer, and an intermetallic compound layer. The intermetallic compound layer is arranged between the first metal layer and the second metal layer.

### CROSS-REFERENCE TO RELATED APPLICATION

This Utility Patent Application claims priority to German Patent Application No. 10 2024 105 602.9 filed Feb. 28, 2024, which is incorporated herein by reference.

### TECHNICAL FIELD

The present disclosure relates to metal components including an intermetallic compound layer. In addition, the present disclosure relates to methods for manufacturing such metal components.

### BACKGROUND

Electronic and semiconductor devices may be identified and traced by markings on the respective device. For example, such a marking may be located on a plastic housing or a metal component of the device. A marking may become illegible when certain processes (such as high temperature processes) are carried out. In view of this, it may be desirable to provide metal components with improved properties and in particular with durable markings. It may further be desirable to provide simple and cost efficient methods for their fabrication.

### SUMMARY

An aspect of the present disclosure relates to a metal component. The metal component comprises a metallic core material, a first metal layer arranged over the metallic core material, a second metal layer arranged over the first metal layer, and an intermetallic compound layer arranged between the first metal layer and the second metal layer.

A further aspect of the present disclosure relates to a method. The method comprises an act of providing a metal component, wherein the metal component comprises: a metallic core material, a first metal layer arranged over the metallic core material, and a second metal layer arranged over the first metal layer. The method further comprises an act of forming an intermetallic compound layer between the first metal layer and the second metal layer.

### BRIEF DESCRIPTION OF THE DRAWINGS

Devices and methods in accordance with the disclosure are described in more detail below based on the drawings. The elements of the drawings are not necessarily to scale relative to each other. Similar reference numerals may designate corresponding similar parts. The technical features of the various illustrated examples may be combined unless they exclude each other and/or can be selectively omitted if not described to be necessarily required.

FIG. 1 schematically illustrates a cross-sectional side view of a metal component 100 in accordance with the disclosure.

FIG. 2 schematically illustrates a cross-sectional side view of a metal component 200 in accordance with the disclosure.

FIG. 3 includes FIGS. 3A to 3E schematically illustrating a cross-sectional side view of a method for manufacturing a metal component in accordance with the disclosure.

FIG. 4 illustrates a flowchart of a method in accordance with the disclosure.

FIG. 5 illustrates a perspective view of an electronic device 500 including a metal component in accordance with the disclosure.

### DETAILED DESCRIPTION

In the following detailed description, reference is made to the accompanying drawings, in which are shown by way of illustration specific aspects in which the disclosure may be practiced. In this regard, directional terminology, such as “top”, “bottom”, “front”, “back”, etc. may be used with reference to the orientation of the figures being described. Since components of described devices may be positioned in a number of different orientations, the directional terminology may be used for purposes of illustration and is in no way limiting. Other aspects may be utilized and structural or logical changes may be made without departing from the concept of the present disclosure. Hence, the following detailed description is not to be taken in a limiting sense, and the concept of the present disclosure is defined by the appended claims.

As used herein, the terms “substantially”, “approximately”, “about”, or the like, may mean “within reasonable tolerances for manufacturing and measurement”. For example, the terms “substantially”, “approximately”, “about”, or the like, may be used herein to account for small manufacturing tolerances or other factors (e.g., within 5%) that are deemed acceptable in the industry without departing from the aspects of the examples described herein. For example, a material layer with an approximate thickness value may practically have a thickness within 5% of the approximate thickness value.

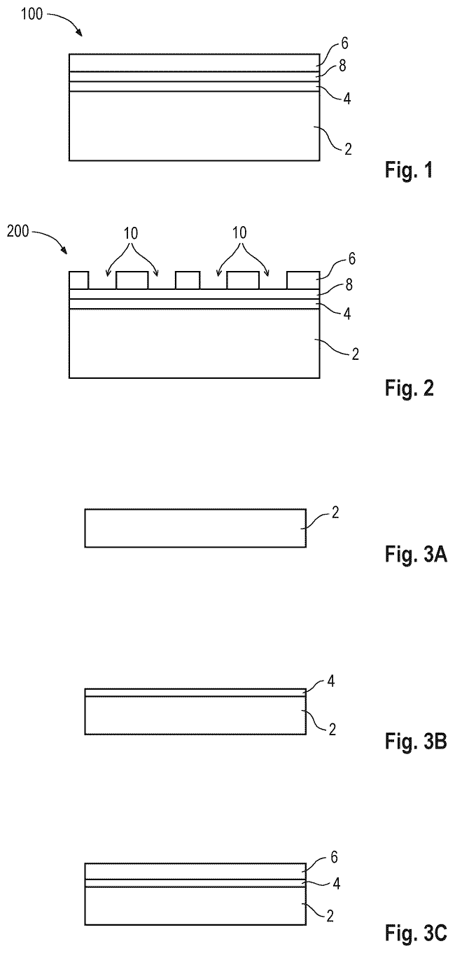

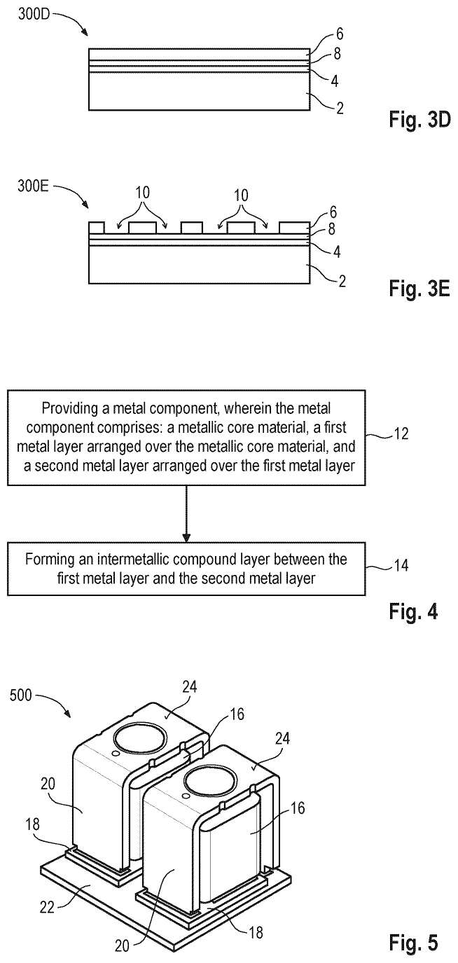

The metal component 100 of FIG. 1 may include a metallic core material 2, a first metal layer 4 arranged over the metallic core material 2, a second metal layer 6 arranged over the first metal layer 4 and an intermetallic compound layer 8 arranged between the first metal layer 4 and the second metal layer 6. Exemplary methods for manufacturing the metal component 100 are described in connection with FIGS. 3 and 4.

The metal component 100 is not restricted to a specific type or application. In particular, the metal component 100 may be a metal component to be used (or configured to be used) in an electronic device, a semiconductor device, a semiconductor package, or the like. A non-limiting example for a device including a metal component in accordance with the disclosure is described in connection with FIG. 5. In one example, the metal component 100 may include or may correspond to a metal clip, a metal pin, a metal lead or a metal ribbon that may be configured to provide an electrical, a mechanical and/or a thermal coupling between two or more components. Alternatively, or additionally, the metal component 100 may include or may correspond to a component of a leadframe, such as a chip carrier, a diepad, a lead, a lead finger or a pin. Alternatively, or additionally, the metal component 100 may include or may correspond to a substrate or a carrier including one or more metal surfaces.

In one example, the metallic core material 2 may include or may be made of at least one of copper, copper alloy, aluminum, or aluminum alloy. In particular, the metallic core material 2 may be manufactured from copper or copper alloy. In the illustrated example, the upper surface of the metallic core material 2 may be substantially planar. In further examples, the upper surface does not necessarily have to be planar and may have an irregular shape.

In one example, the first metal layer 4 may include or may be made of nickel or nickel alloy. For example, the first metal layer 4 may have a thickness in a range from about 1 μm to about 2 μm when measured in the vertical direction. In particular, the thickness of the first metal layer 4 may have a substantially constant value. In the illustrated example, the first metal layer 4 may have been formed on the substantially planar upper surface of the metallic core material 2, and the upper surface of the first metal layer 4 may be planar as well. The first metal layer 4 may cover the entire metallic core material 2 or only selected parts of it, such as only the upper surface of the material 2.

In one example, the second metal layer 6 may include or may be made of tin or tin alloy. For example, a thickness of the second metal layer 6 may be at least about 2 μm when measured in the vertical direction. In a more specific example, the thickness of the second metal layer 6 may be in a range from about 7 μm to about 10 μm when measured in the vertical direction. In particular, the thickness of the second metal layer 6 may have a substantially constant value. In the illustrated example, the second metal layer 6 may have been formed on the substantially planar upper surface of the first metal layer 4, and the upper surface of the second metal layer 6 may be planar as well. In the illustrated example, the second metal layer 6 may fully cover the first metal layer 4. In further examples, the second metal layer 6 may only partially cover the first metal layer 4, such as described below in connection with the example of FIG. 2. A hardness of the second metal layer 6 may be smaller than a hardness of the first metal layer 4.

In one example, the intermetallic compound layer 8 may include or may be made of a nickel-tin intermetallic compound. In particular, the intermetallic compound layer 8 may have been formed from the materials of the first metal layer 4 and the second metal layer 6, as e.g. described in connection with the method of FIG. 3. For example, the intermetallic compound layer 8 may have a thickness in a range from about 1 μm to about 2 μm when measured in the vertical direction. In particular, the thickness of the intermetallic compound layer 8 may have a substantially constant value. In the illustrated example, the intermetallic compound layer 8 may have been formed between the substantially planar metal layers 4 and 6 and may thus be formed substantially planar as well. A hardness of the intermetallic compound layer 8 may be larger than a hardness of the second metal layer 6.

The metal component 200 of FIG. 2 may include some or all features of the metal component 100 of FIG. 1. The second metal layer 6 of the metal component 200 may include one or more openings 10 exposing a part of the intermetallic compound layer 8. In the illustrated exemplary side view, the openings 10 may have a substantially rectangular shape. However, the openings 10 are not restricted in this regard and may have different shapes in further examples.

The exposed part of the intermetallic compound layer 8 (or the openings 10) may form a marking on an outer surface of the metal component 200. In the illustrated example, the marking may be arranged at the upper surface of the metal component 200. The marking may be configured to identify and/or trace the metal component 200 or a device including the metal component 200. For example, the marking may represent a text, a name, a code or a label for identifying the device, such as a product name, a product code, a product number, or the like. Alternatively, or additionally, the marking may represent a property of the device and/or a property of a manufacturing of the device. Alternatively, or additionally, the marking may represent product-related information of the device, such as a stock number, a lot number, a batch number, a production date, or the like.

The marking is not restricted to a specific type or shape. For example, the marking may include or may correspond to at least one of a number, a letter, a character, a symbol, or a sequence or string thereof. In the illustrated exemplary side view, the marking formed by the openings 10 may be obscured due to the chosen perspective. However, when e.g. viewed in the vertical direction, the openings 10 may form the at least one number, letter, character, symbol, or sequence or string thereof. In a non-limiting and purely illustrative example, the openings 10 may form a marking which may read “TDM22544D”.

The exposed part of the intermetallic compound layer 8 (and thus the marking formed by the openings 10) may include a non-wetting behavior against molten tin. That is, molten tin does not necessarily spread and/or adhere to the surface of the marking. Accordingly, when a high temperature process (such as a reflow soldering process) is performed, the marking formed by the openings 10 and its legibility is not necessarily impacted. For example, a reflow process may be performed at a temperature of approximately 260° C., whereas the melting point of the second metal layer 6 (in the case of a tin layer) may be at a temperature of around 230° C. Even after multiple reflow processes the marking formed by the exposed part of the intermetallic compound layer 8 may remain unaffected due to its non-wetting behavior against molten tin. As a result, the metal component 200 may provide a robust and durable marking for a device including the metal component 200.

The metal component 200 may optionally include a tin oxide layer (not shown) that may partially cover the intermetallic compound layer 8. In the illustrated example, the tin oxide layer may partially cover the upper surface of the intermetallic compound layer 8. For example, the tin oxide layer may be obtained when forming the openings 10 in the second metal layer 6 as will be described in more detail below in connection with FIG. 3E. However, it is to be understood that the portions of tin oxide may be regarded as optional and do not necessarily affect a non-wetting behavior of the intermetallic compound layer 8 against molten tin. When measured in the vertical direction, a thickness of the tin oxide layer may be smaller than one or more of the thicknesses of the first metal layer 4, the second metal layer 6 and the intermetallic compound layer 8.

FIGS. 3A to 3E illustrate a method for manufacturing a metal component in accordance with the disclosure. For example, the method may be used for manufacturing the metal components 100 and 200 of FIGS. 1 and 2.

In FIG. 3A, a metallic core material 2 may be provided. For example, the metallic core material 2 may include or may be manufactured from at least one of copper, copper alloy, aluminum, or aluminum alloy.

In FIG. 3B, a first metal layer 4 may be formed over the metallic core material 2. The first metal layer 4 may include or may be made of nickel or nickel alloy. In this case, forming the first metal layer 4 may include or correspond to plating the metallic core material 2 with a nickel layer. For example, the nickel layer may have a thickness in a range from 1 μm to 2 μm when measured in the vertical direction.

In FIG. 3C, a second metal layer 6 may be formed over the first metal layer 4. The second metal layer 6 may include or may be made of tin or tin alloy. In this case, forming the second metal layer 6 may include or correspond to plating the first metal layer 4 with a tin layer. For example, a thickness of the tin layer may be at least 2 μm when measured in the vertical direction. In a more specific example, the thickness of the second metal layer 6 may be in a range from about 7 μm to about 10 μm when measured in the vertical direction.

In FIG. 3D, an intermetallic compound layer 8 may be formed between the first metal layer 4 and the second metal layer 6. In particular, the intermetallic compound layer 8 may include or correspond to a nickel-tin intermetallic compound. In one example, the intermetallic compound layer 8 may be formed by performing a reflow process. Here, the intermetallic compound layer 8 may be formed during heating from the materials of the first metal layer 4 and the second metal layer 6. The intermetallic compound layer 8 may be in direct contact with the first metal layer 4 and/or in direct contact with the second metal layer 6. More specific, the upper surface of the first metal layer 4 may be in direct contact with the bottom surface of the intermetallic compound layer 8 and/or the upper surface of the intermetallic compound layer 8 may be in direct contact with the bottom surface of the second metal layer 6. For example, the intermetallic compound layer 8 may have a thickness in a range from about 1 μm to about 2 μm when measured in the vertical direction. The metal component 300D obtained after performing the act of FIG. 3D may be similar to the metal component 100 of FIG. 1.

In FIG. 3E, the second metal layer 6 may be partially removed at selected positions, wherein a part of the intermetallic compound layer 8 may be exposed. In one example, removing the corresponding parts of the second metal layer 6 may include performing a laser ablation process. Due to a higher hardness and a higher melting point of the intermetallic compound layer 8 compared to the second metal layer 6 the laser ablation process may be self-terminated when the intermetallic compound layer 8 gets exposed. For example, the melting temperature of a tin layer 6 may be about 230° C. while the melting temperature of a nickel-tin intermetallic compound may be about 795° C. It is to be understood that parameters of the laser ablation process (e.g. laser power, laser frequency, marking speed, pulse duration, repetition rate, etc.) may be adjusted to material properties of the second metal layer 6 and the intermetallic compound layer 8. When performing the laser ablation process, tin of the tin layer 6 may be partially oxidized, thereby forming residual portions of a tin oxide layer on the intermetallic compound layer 8. However, it is to be understood that these residual portions of tin oxide may be regarded as optional and do not necessarily affect a non-wetting behavior of the intermetallic compound layer 8 against molten tin as previously described.

After the selected parts of the second metal layer 6 have been removed, the exposed part of the intermetallic compound layer 8 may form a marking on an outer surface of the manufactured metal component 300E as previously described. The metal component 300E obtained after performing the act of FIG. 3E may be similar to the metal component 200 of FIG. 2.

FIG. 4 illustrates a flowchart of a method in accordance with the disclosure. The method may be seen as a more general version of the method described in connection with FIG. 3. The method of FIG. 4 may be extended by any aspect described in connection with other examples. The method may be used for manufacturing metal components in accordance with the disclosure.

At 12, a metal component may be provided. The metal component may include a metallic core material, a first metal layer arranged over the metallic core material and a second metal layer arranged over the first metal layer. For example, the provided metal component may be similar to the metal component of FIG. 3C. At 14, an intermetallic compound layer may be formed between the first metal layer and the second metal layer. For example, the act 14 may be similar to the act of FIG. 3D.

It is to be understood that the method of FIG. 4 may include one or more further acts. For example, the method may be extended by an act of partially removing the second metal layer as described in connection with FIG. 3E. Alternatively, or additionally, the method may be extended by one or more of the acts described in connection with FIGS. 3A to 3C.

FIG. 5 shows an exemplary and non-limiting example of an electronic device 500 including a metal component in accordance with the disclosure. However, it is to be understood, that an application or usage of metal components as described herein is not restricted to the specific example of FIG. 5.

The electronic device 500 may correspond to a dual-phase power module including one or more inductors 16, one or more power stages 18 and one or more metal components 20. For example, the components of the electronic device 500 may be arranged on a printed circuit board 22. In the illustrated non-limiting case, the electronic device 500 may include an exemplary number of two inductors 16, two power stages 18 and two metal components 20. It is to be understood that the electronic device 500 may include further components which are not discussed for the sake of simplicity. An inductor 16 may be arranged between a respective power stage 18 and a respective metal component 20. The respective metal component 20 may be configured to mechanically and/or electrically couple the inductor 16 and/or the power stage 18 to the printed circuit board 22. In addition, the respective metal component 20 may be configured as a heatsink. The inductor 16 may be configured to cool the power stage 18 by thermally coupling the power stage 18 to the metal component 20.

In the illustrated example, each of the metal components 20 may correspond to or may include a u-shaped metal clip 20 that may encompass the respective inductor 16. Note that the electronic device 500 does not necessarily include a plastic housing as other semiconductor packages. That is, a marking on an external surface of the electronic device 500 cannot be located on such plastic housing, but needs to be arranged elsewhere on the electronic device 500. In accordance with previously described examples a marking may be arranged on the metal clip 20. For example, a marking may be arranged on the upper surface 24 of the respective metal clip 20.

### EXAMPLES

In the following, metal components in accordance with the disclosure and methods for manufacturing such metal components are described by means of examples.

Example 1 is a metal component, comprising: a metallic core material; a first metal layer arranged over the metallic core material; a second metal layer arranged over the first metal layer; and an intermetallic compound layer arranged between the first metal layer and the second metal layer.

Example 2 is a metal component according to Example 1, wherein the first metal layer comprises nickel, the second metal layer comprises tin, and the intermetallic compound layer comprises a nickel-tin intermetallic compound.

Example 3 is a metal component according to Example 1 or 2, wherein the second metal layer comprises one or more openings exposing a part of the intermetallic compound layer.

Example 4 is a metal component according to Example 3, wherein the exposed part of the intermetallic compound layer comprises a non-wetting behavior against molten tin.

Example 5 is a metal component according to Example 3 or 4, wherein the exposed part of the intermetallic compound layer forms a marking on an outer surface of the metal component.

Example 6 is a metal component according to Example 5, wherein the marking comprises at least one of a number, a letter, a character, or a symbol.

Example 7 is a metal component according to any of the preceding Examples, wherein the metallic core material comprises at least one of copper, copper alloy, aluminum, or aluminum alloy.

Example 8 is a metal component according to any of the preceding Examples, wherein: the first metal layer has a thickness in a range from 1 μm to 2 μm, and/or the intermetallic compound layer has a thickness in a range from 1 μm to 2 μm.

Example 9 is a metal component according to any of the preceding Examples, further comprising: a tin oxide layer at least partially covering the intermetallic compound layer.

Example 10 is a metal component according to any of the preceding Examples, wherein the metal component comprises a metal clip, a component of a leadframe, or a substrate including a metal surface.

Example 11 is a method, comprising: providing a metal component, wherein the metal component comprises: a metallic core material, a first metal layer arranged over the metallic core material, and a second metal layer arranged over the first metal layer; and forming an intermetallic compound layer between the first metal layer and the second metal layer.

Example 12 is a method according to Example 11, further comprising: partially removing the second metal layer, thereby exposing a part of the intermetallic compound layer.

Example 13 is a method according to Example 12, wherein partially removing the second metal layer comprises performing a laser ablation process.

Example 14 is a method according to Example 12 or 13, wherein the exposed part of the intermetallic compound layer forms a marking on an outer surface of the metal component.

Example 15 is a method according to any of Examples 11 to 14, wherein forming the intermetallic compound layer comprises performing a reflow process.

Example 16 is a method according to any of Examples 11 to 15, further comprising: forming the first metal layer over the metallic core material, wherein forming the first metal layer comprises plating the metallic core material with a nickel layer.

Example 17 is a method according to Example 16, wherein the nickel layer has a thickness in a range from 1 μm to 2 μm.

Example 18 is a method according to any of Examples 11 to 17, further comprising: forming the second metal layer over the first metal layer, wherein forming the second metal layer comprises plating the first metal layer with a tin layer.

Example 19 is a method according to Example 18, wherein a thickness of the tin layer is at least 2 μm.

As employed in this description, the terms “connected”, “coupled”, “electrically connected”, and/or “electrically coupled” may not necessarily mean that elements must be directly connected or coupled together. Intervening elements may be provided between the “connected”, “coupled”, “electrically connected”, or “electrically coupled” elements.

Further, the words “over” and “on” used with regard to e.g. a material layer formed or located “over” or “on” a surface of an object may be used herein to mean that the material layer may be located (e.g. formed, deposited, etc.) “directly on”, e.g. in direct contact with, the implied surface. The words “over” and “on” used with regard to e.g. a material layer formed or located “over” or “on” a surface may also be used herein to mean that the material layer may be located (e.g. formed, deposited, etc.) “indirectly on” the implied surface with e.g. one or more additional layers being arranged between the implied surface and the material layer.

Furthermore, to the extent that the terms “having”, “containing”, “including”, “with”, or variants thereof are used in either the detailed description or the claims, such terms are intended to be inclusive in a manner similar to the term “comprising”. That is, as used herein, the terms “having”, “containing”, “including”, “with”, “comprising”, and the like are open-ended terms that indicate the presence of stated elements or features, but do not preclude additional elements or features. The articles “a”, “an”, and “the” are intended to include the plural as well as the singular, unless the context clearly indicates otherwise.

Moreover, the word “exemplary” is used herein to mean serving as an example, instance, or illustration. Any aspect or design described herein as “exemplary” is not necessarily to be construed as advantageous over other aspects or designs. Rather, use of the word exemplary is intended to present concepts in a concrete fashion. As used in this application, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the previous instances. In addition, the articles “a” and “an” as used in this application and the appended claims may generally be construed to mean “one or more” unless specified otherwise or clear from context to be directed to a singular form. Also, at least one of A and B or the like generally means A or B or both A and B.

Devices and methods for manufacturing devices are described herein. Comments made in connection with a described device may also hold true for a corresponding method and vice versa. For example, if a specific component of a device is described, a corresponding method for manufacturing the device may include an act of providing the component in a suitable manner, even if such act is not explicitly described or illustrated in the figures.

Although the disclosure has been shown and described with respect to one or more implementations, equivalent alterations and modifications will occur to others skilled in the art based at least in part upon a reading and understanding of this description and the annexed drawings. The disclosure includes all such modifications and alterations and is limited only by the concept of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure which performs the function in the herein illustrated exemplary implementations of the disclosure. In addition, while a particular feature of the disclosure may have been disclosed with respect to only one of several implementations, such feature may be combined with one or more other features of the other implementations as may be desired and advantageous for any given or particular application.

1. A metal component, comprising:
a metallic core material;
a first metal layer arranged over the metallic core material;
a second metal layer arranged over the first metal layer; and
an intermetallic compound layer arranged between the first metal layer and the second metal layer,
wherein the second metal layer comprises one or more openings exposing a part of the intermetallic compound layer.

2. The metal component of claim 1, wherein the first metal layer comprises nickel, the second metal layer comprises tin, and the intermetallic compound layer comprises a nickel-tin intermetallic compound.

3. The metal component of claim 1, wherein the exposed part of the intermetallic compound layer comprises a non-wetting behavior against molten tin.

4. The metal component of claim 1, wherein the exposed part of the intermetallic compound layer forms a marking on an outer surface of the metal component.

5. The metal component of claim 4, wherein the marking comprises at least one of a number, a letter, a character, or a symbol.

6. The metal component of claim 1, wherein the metallic core material comprises at least one of copper, copper alloy, aluminum, or aluminum alloy.

7. The metal component of claim 1, wherein:
the first metal layer has a thickness in a range from 1 μm to 2 μm, and/or
the intermetallic compound layer has a thickness in a range from 1 μm to 2 μm.

8. The metal component of claim 1, further comprising:
a tin oxide layer at least partially covering the intermetallic compound layer.

9. The metal component of claim 1, wherein the metal component comprises a metal clip, a component of a leadframe, or a substrate including a metal surface.

10. A method, comprising:
providing a metal component, wherein the metal component comprises:
a metallic core material,
a first metal layer arranged over the metallic core material, and
a second metal layer arranged over the first metal layer;
forming an intermetallic compound layer between the first metal layer and the second metal layer; and
partially removing the second metal layer, thereby exposing a part of the intermetallic compound layer.

11. The method of claim 10, wherein partially removing the second metal layer comprises performing a laser ablation process.

12. The method of claim 10, wherein the exposed part of the intermetallic compound layer forms a marking on an outer surface of the metal component.

13. The method of claim 10, wherein forming the intermetallic compound layer comprises performing a reflow process.

14. The method of claim 10, further comprising:
forming the first metal layer over the metallic core material, wherein forming the first metal layer comprises plating the metallic core material with a nickel layer.

15. The method of claim 14, wherein the nickel layer has a thickness in a range from 1 μm to 2 μm.

16. The method of claim 10, further comprising:
forming the second metal layer over the first metal layer, wherein forming the second metal layer comprises plating the first metal layer with a tin layer.

17. The method of claim 16, wherein a thickness of the tin layer is at least 2 μm.
